(19) United States
(12) Patent Application Publication
(10) Pub. No.: US 2006/0055992 A1
(43) Pub. Date: Mar. 16, 2006

(54) Display device having electronic album function and method for controlling the same

(75) Inventor: Byung Joon Koo, Gumi-si (KR)

Correspondence Address: BIRCH STEWART KOLASCH & BIRCH, PO BOX 747, FALLS CHURCH, VA, 22040-0747, US

(73) Assignee: LG Electronics Inc.

(21) Appl. No.: 11/224,125

(22) Filed: Sep. 13, 2005

(30) Foreign Application Priority Data
Sep. 14, 2004 (KR) 10-2004-73323

(51) Int. Cl. G03F 3/10

(52) U.S. Cl. 358/527

(57) ABSTRACT

Disclosed is a display device having an electronic album function and a method for controlling the same in which video and audio data are displayed per anniversary at a user's desired schedule. The electronic album includes a memory to prestore event information associated with at least one event, and a controller to selectively present video and/or audio data associated with the event based on the prestored event information.

This application claims the benefit of the Korean Patent Application No. P2004-73323 filed on Sep. 14, 2004, which is hereby incorporated by reference as if fully set forth herein.

### BACKGROUND OF THE INVENTION

1. Field of the Invention

The present invention relates to a display device and a method for controlling the same, and more particularly, to a display device having an electronic album function and a method for controlling the same in which corresponding photos are automatically displayed in the display device depending on user's desired conditions.

2. Background of the Related Art

Generally, an electronic album function is configured to improve a conventional paper album. The electronic album function records a plenty of photos in an image recording medium to obtain a compact size and displays the photos to allow a user to view them if necessary. Specifically, the electronic album function is to read, store, and display picture data in the image recording medium through a digital camera and so on or to read, write, store, display and record the picture data through direct/indirect picture data compatible mode (communication) with peripheral devices such as TV, personal computer, PDA, and PMP.

Recently, display devices having such an electronic album function have been developed. A display device having an electronic album function is set to display video data obtained by capturing broadcasting screens and video data stored in an internal or external memory in a manner such as thumbnail images, entire screen, or slide show.

FIG. 1 illustrates a related art display device having an electronic album function. Referring to FIG. 1, the related art display device includes a signal input portion 3, a scaler 4, a memory 7, a key input portion 1, a switching portion 5, and a display portion 6. The signal input portion 3 receives an input signal received through either an antenna or an external device. The scaler 4 converts the input signal inputted through the signal input portion 3 to be suitable for the format supported by the corresponding display module. The memory 7 stores a plurality photo information in accordance with the user settings. The key input portion 1 is used for inputting request commands made by the user. The switching portion 5 is used for selectively outputting the photo information stored in the memory 7 in accordance with the user request command inputted through the key input portion 1. The display portion 6 displays the input signal switched by the switching portion 5.

FIG. 2 illustrates a method of controlling the related art display device having the electronic album function. Referring to FIG. 2, the display device verifies whether the user turned the power of the display device on (S11). If the power is turned on, the display device verifies whether the user selected the electronic album function (S12). If the user has selected the electronic album function, the display device determines whether the user selected a specific photo, which the user wishes to display (S13). If the user has selected a specific photo, the display device simply displays the specific photo at the time the user selects the photo.

In the related art electronic album function, if a user selects an electronic album folder, the entire screen of photos stored in the electronic album folder is displayed and the user can select a desired photo from the entire screen. The user can select any desired one of a slide show function, a copy function, and a delete function for the selected photo.

However, the related art electronic album function is configured to simply display photos or pictures stored in the internal or external memory in the display device. Also, the related art electronic album function restricts utilization of the electronic album. Therefore, it is difficult for the related art electronic album function to fulfill user's desire.

### SUMMARY OF THE INVENTION

Accordingly, the present invention is directed to provide a display device having an electronic album function and a method for controlling the same that substantially obviates one or more problems due to limitations and disadvantages of the related art.

An object of the present invention is to provide a display device having an electronic album function and a method for controlling the same in which photos or video data such as moving pictures stored in the display device are set by a user to be displayed at a special anniversary and an electronic album is edited depending on the individual timing schedule at a user's desire.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, according to an aspect of the present invention, a display device having an electronic album function includes a key input portion receiving anniversary setting data, a memory storing the anniversary setting data input through the key input portion, a controller selecting video data and audio data previously stored in an electronic album based on the anniversary setting data, a display portion outputting the selected video data based on the anniversary setting data, and a speaker outputting the selected audio data based on the anniversary setting data.

In another aspect of the present invention, a display device includes a key input portion, a memory, a controller, a display portion, a speaker, and an Internet server transmitting video and audio data corresponding to anniversary set by a user to an outer display device depending on a control signal of the controller. Preferably, the outer display device includes an Internet server.

In another aspect of the present invention, a method for controlling a display device having an electronic album function includes the steps of a) inputting video data, audio data, and text messages corresponding to an anniversary in accordance with a user's request, b) storing the input data and text messages per anniversary in accordance with a user's request, and c) outputting the stored data at a corresponding anniversary.

According to an embodiment of the present invention, there is provided a method of controlling an electronic album, the method comprising: prestoring, in the electronic album, event information associated with at least one event; and selectively presenting video and/or audio data associated with the at least one event based on the prestored event information.

According to an embodiment of the present invention, there is provided an electronic album comprising: a memory to prestore event information associated with at least one event; and a controller to selectively present video and/or audio data associated with the at least one event based on the prestored event information.

According to an embodiment of the present invention, there is provided a method for controlling an electronic album, the method comprising: setting a folder of images to be stored in a memory in accordance with a user's request; displaying the images of the set folder; editing the folder at the user's request referring to the displayed images; and displaying the edited folder and additional messages in accordance with the user's request to control the electronic album.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 illustrates a related art display device having an electronic album function;

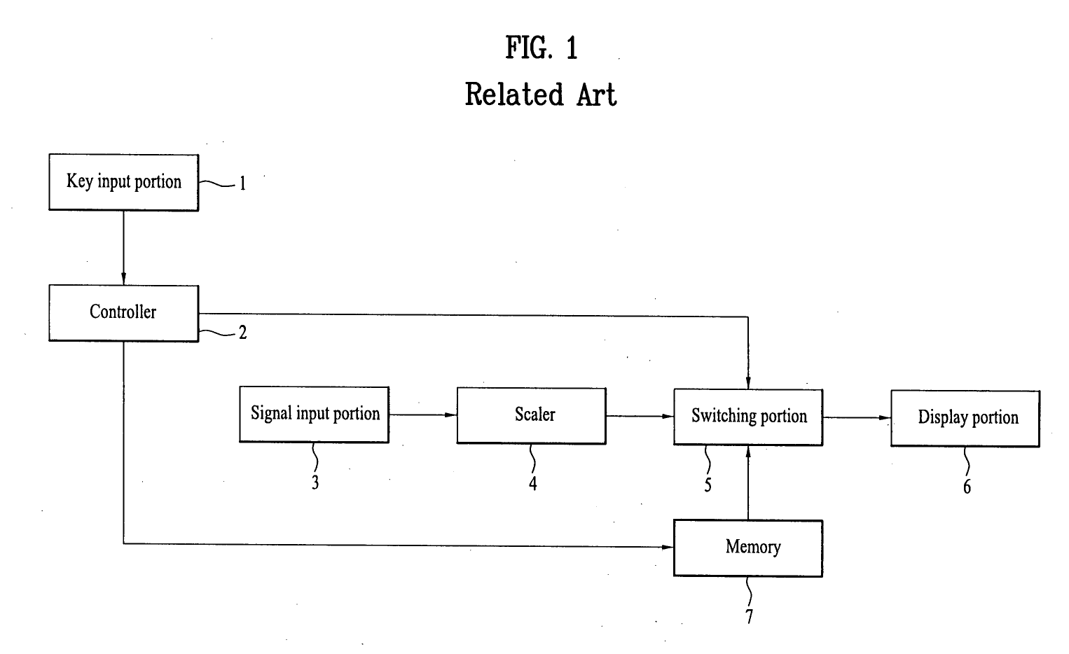

FIG. 2 illustrates a method of controlling the related art display device having the electronic album function;

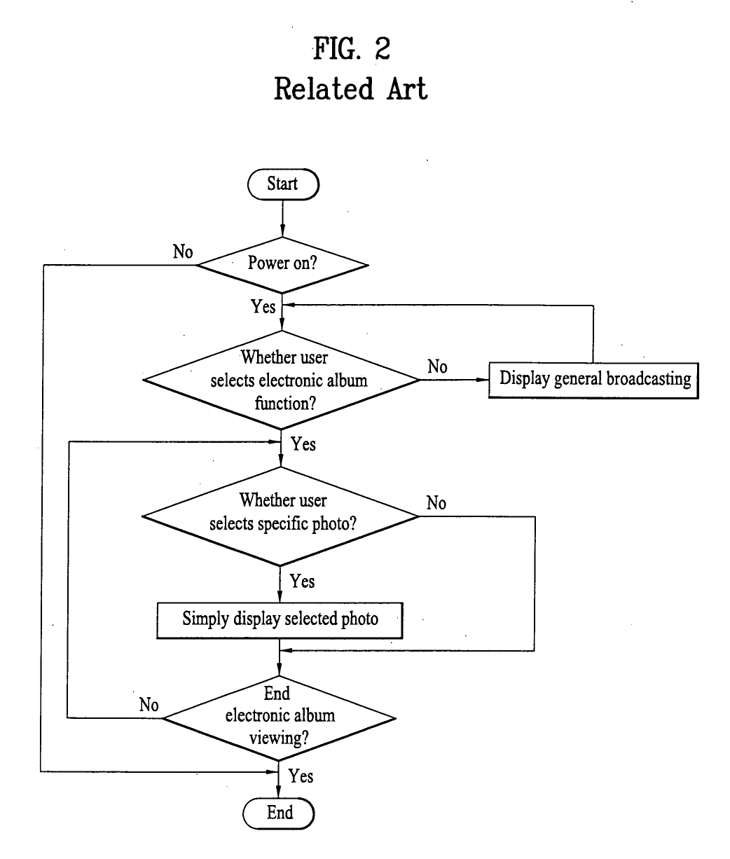

FIG. 3 illustrates a display device having an electronic album function according to the present invention;

FIG. 4 illustrates an exemplary screen of a display device having an electronic album function according to the present invention;

FIG. 5 illustrates another exemplary screen of a display device having an electronic album function according to the present invention;

FIG. 6 illustrates an exemplary screen of a display device having another electronic album function according to the present invention;

FIG. 7 illustrates a method for controlling a display device having an electronic album function according to the present invention; and

FIG. 8 illustrates other exemplary screen of a display device having an electronic album function according to the present invention.

### DETAILED DESCRIPTION OF THE PREFERRED EMBODIMENTS

Reference will now be made in detail to the preferred embodiments of the present invention, examples of which are illustrated in the accompanying drawings.

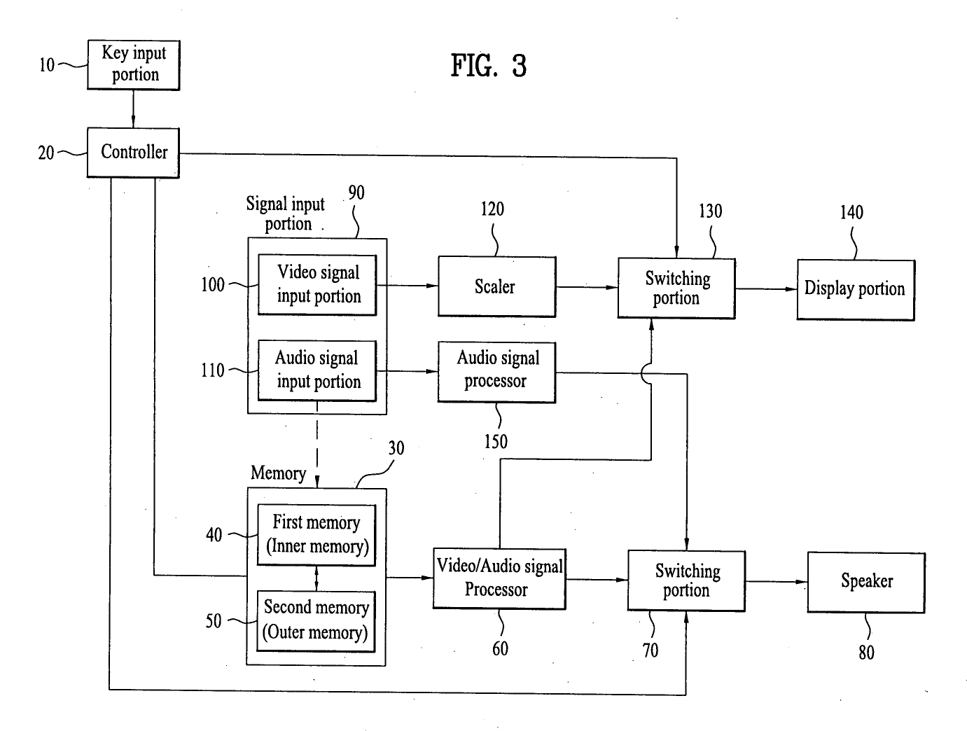

FIG. 3 illustrates a display device having an electronic album function according to the present invention. Referring to FIG. 3, a user's request command signal is transmitted to a controller 20 through a key input portion 10. The controller 20 stores video data and audio data corresponding to a special anniversary in a memory 30 depending on the user's request command signal. The video data and the audio data stored in the memory 30 are transmitted to a video/audio signal processor 60. The video/audio signal processor 60 transmits the video data to a switching portion 130 and the audio data to another switching portion 70 depending on a control signal of the controller 20.

Meanwhile, video data and audio data are respectively applied to a video signal input portion 100 and an audio signal input portion 110. The video and audio data for air wave or cable broadcasting may be received through an antenna. Alternatively, the video and audio data may also be received from an external device.

The video data applied to the video signal input portion 100 are transmitted to the switching portion 130 through a scaler 120 that modulates the video data to a signal suitable for a corresponding display module format. Any one of the video data applied through the above broadcasting and the video data previously stored in the memory 30 or both of them may be displayed depending on the control signal of the controller 20.

The audio data applied to the audio signal input portion 110 are transmitted to the switching portion 70 through an audio signal processor 150 that processes the audio data to a signal suitable for a corresponding speaker module. Any one of the audio data applied through the above broadcasting and the audio data previously stored in the memory 30 or both of them may be displayed depending on the control signal of the controller 20.

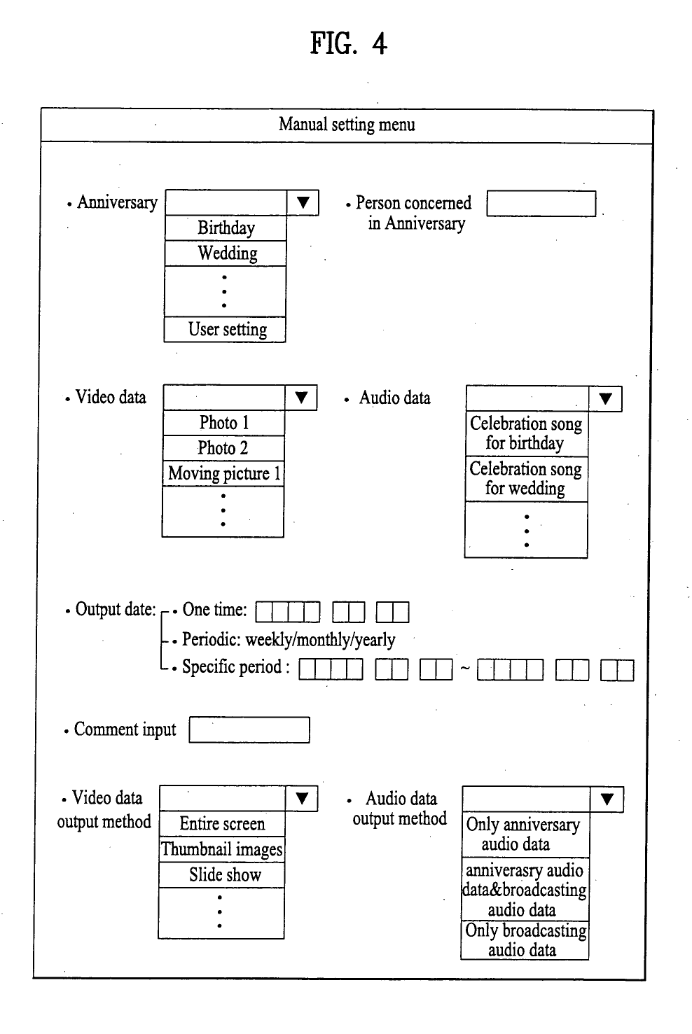

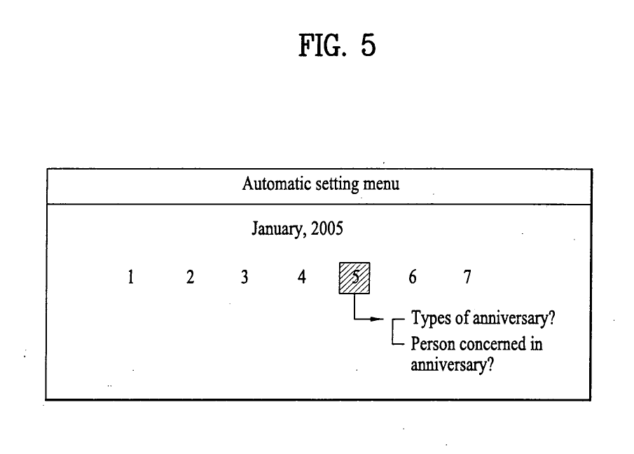

A user inputs various data on anniversaries in the key input portion 10 in which the user's request command signal is input, and sets a display manner. The display manner will be described in detail with reference to FIG. 4 and FIG. 5.

The user can select a manual setting menu or an automatic setting menu to input various data on the anniversaries and set the display manner.

First, an example of the manual setting menu will be described referring to FIG. 4. The user can select any one of folders on birthday, wedding, graduation, and the like from anniversary options. Of course, the user can produce a new folder in accordance with user's setting. The user can input the person concerned in the selected anniversary and select video data and audio data corresponding to the selected anniversary. Also, the user can output the corresponding data and input a particular text message. The user can determine output date of the above data and the text message.

Finally, the user can output the video data previously stored in the memory in various display types. For example, the user can determine any one of the display types such as entire screen, thumbnail images, and slide show. Also, the user can output the audio data previously stored in the memory in various output methods. For example, the user can select whether to output any one of the audio data previously stored in the memory and the audio data currently in broadcasting or both of them. As shown in FIG. 4, the output date may be set to one of one time output, periodic output, and specific period output. More specifically, the video data and the audio data may be outputted only once on a specific data inputted by the user. The video data and the audio data may also be outputted periodically on a weekly, monthly, or yearly basis. Furthermore, the user may also set up a specific output period so as to output the video data and the audio data during this specific period, i.e., starting from a specific year/month/date to another specific year/month/date.

An example of the automatic setting menu will be described referring to FIG. 5. Even in case that the user inputs only basic data of the anniversary, video data and audio data relating to the anniversary are automatically output at the time when the anniversary is coming. For example, the basic data on the anniversary may be date of the anniversary, type of the anniversary, and the person concerned in the anniversary.

If the user selects the automatic setting menu, a calendar screen is displayed. Then, the user can click a special date from the calendar to select a type of the anniversary and the person concerned in the anniversary. If the anniversary corresponding to the special date selected by the user is coming, the controller automatically retrieves titles of the audio and video data previously stored in the memory to output the retrieved data at the special date. The controller automatically selects the display type. For example, the video data, the audio data, and the display type may be determined in a random manner or a particular manner. In the particular manner, the latest input data among the retrieved data may be selected and the display type may be the entire screen.

The controller 20 transmits the control signal to the memory 30, the video/audio signal processor 60, and the switching portions 70 and 130 to output particular data at the special anniversary depending on user's request command input through the key input portion 10.

The memory 30 includes a first memory (inner memory) 40 and a second memory (outer memory) 50. The first memory 40 stores the video data applied through broadcasting in capture images or moving pictures, and records the audio data applied through broadcasting to be stored therein. An outer device such as external hardware or external PVR is used as the second memory 50. The particular data determined by the controller 20 among the data stored in the first memory 40 and the second memory 50 are only transmitted to the video/audio signal processor 60.

The video/audio signal processor 60 transmits the particular video data to the switching portion 130 and the particular audio data to the switching portion 70 at a particular time depending on the control signal of the controller 20.

The switching portions 130 and 70 respectively transmit only the received video and audio data to a display portion 140 and a speaker 80 depending on the control signal of the controller 20. Alternatively, the switching portions 130 and 70 may respectively transmit both the received video and audio data and video and audio signals of broadcasting being received in the display device to the display portion 140 and the speaker 80.

The display portion 140 displays the video data in any one type of the entire screen, thumbnail images, and slide show. The speaker 80 outputs the audio data received from the switching portion 70.

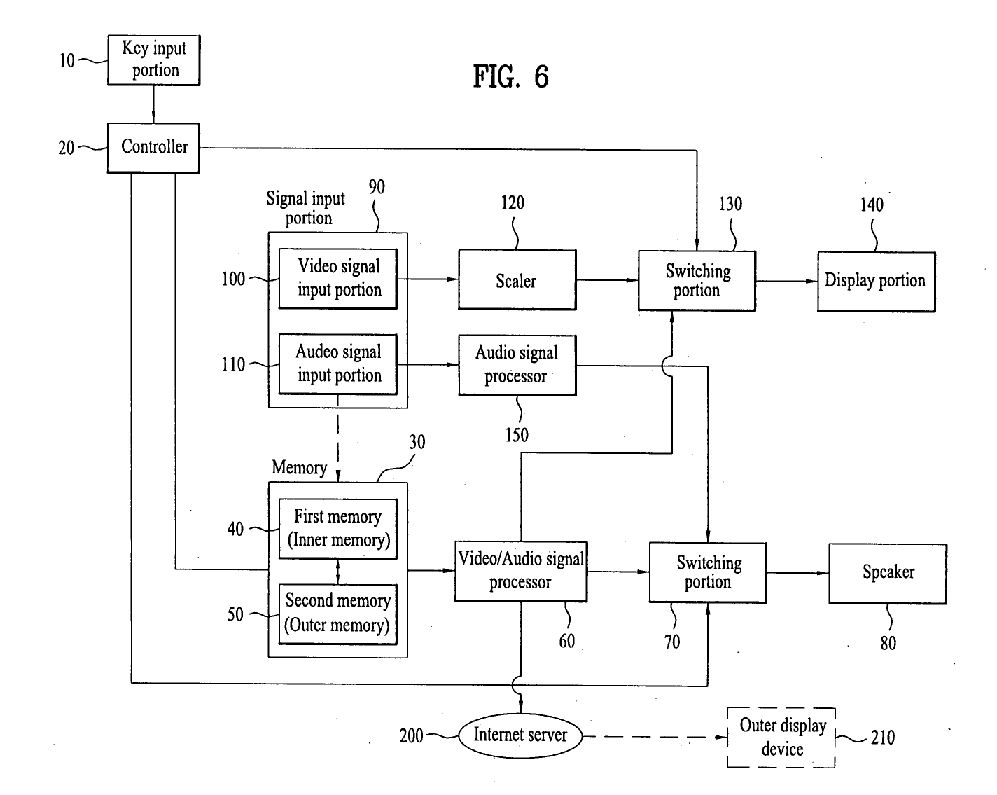

The display device having another electronic album function of the present invention will be described with reference to FIG. 6. The basic constitution of FIG. 6 is the same as that of FIG. 3. In FIG. 6, an Internet server 200 is additionally provided. Unlike FIG. 3, the video and audio data applied to the video/audio signal processor 60 are transmitted to the Internet server 200 as well as the switching portions 70 and 130. The data transmitted to the Internet server 200 are transmitted to another outer display device 210 having a particular address set by the user and displayed therein. The outer display device 210 may be any one of devices such as a cellular phone, PDA, PMP, computer, and Internet TV. However, the outer display device 210 is not limited to such devices but includes all the display devices that can be connected to Internet.

Even in case that the video and audio data are output to the display device at a special date, the person concerned in the special anniversary may not identify the data if the person concerned in the particular anniversary is not in a place where the display device is provided. However, as shown in FIG. 5, the display device provided with the Internet server 200 can output the particular data through the display portion 140 and the speaker 80 and at the same time transmit the particular data to another display device which the person concerned in the anniversary posses, i.e., the outer display device 210. Therefore, the person concerned in the anniversary away from the display device of the present invention can receive the particular data.

In this respect, the display device having the Internet server is preferably configured as shown in FIG. 4 while the display device having no Internet server is preferably configured as shown in FIG. 3.

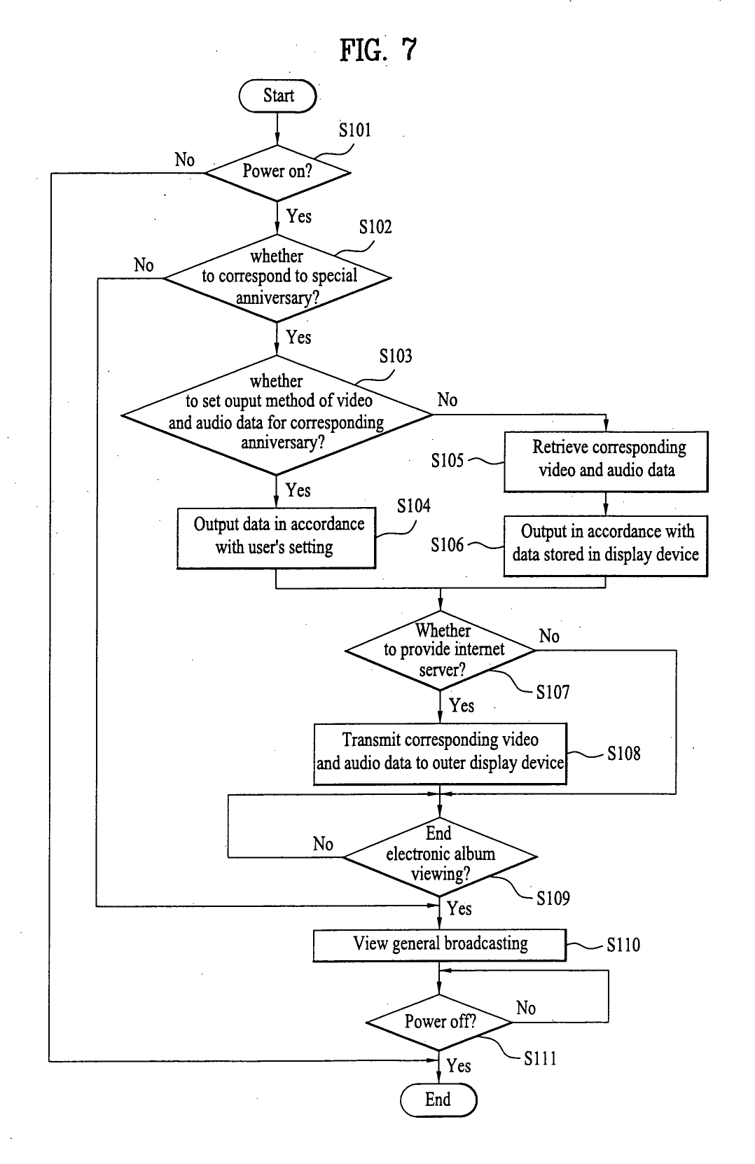

A method for controlling the display device having an electronic album function according to the present invention will be described with reference to FIG. 7.

First, if a power-on command is input by the user, it is determined whether a special anniversary is set based on the power-on timing point in steps S101 and S102.

As a result of the step S102, if the special anniversary is set, the controller determines whether video data, audio data, and a display manner relating to the corresponding anniversary are set in addition to basic data on a corresponding anniversary input through the key input portion by the user, such as date of the anniversary, type of the anniversary, and the person concerned in the anniversary, in step S103.

If the video data, the audio data, and the display manner in addition to the basic data on the corresponding anniversary are set as a result of the step S103, the display portion and the speaker output the video data and the audio data depending on user's setting in step S104. However, if the basic data on the corresponding anniversary, such as date of the anniversary, type of the anniversary, and the person concerned in the anniversary, are only set without the video data, the audio data, and the display manner, the controller retrieves the corresponding video and audio data based on the basic data in step S105. The retrieved video and audio data are respectively output through the display portion and the speaker. If the retrieved video and audio data are greater than two, respectively, it is selected in a random manner or a particular manner whether to output which data among the retrieved data and whether to output the selected data in which display type in step S106.

Subsequently, the controller determines whether the Internet server is in the display device in step S107.

If the Internet server is in the display device as a result of the step S107, the video data and the audio data are transmitted to the outer display device in step S108.

Next, it is determined whether to end viewing of the electronic album on the anniversary in step S109.

If the user ends viewing of the electronic album as a result of the step S109, the user views general broadcasting in step S110.

If the user commands power-off, activity of the system is ended with regard to the display device.

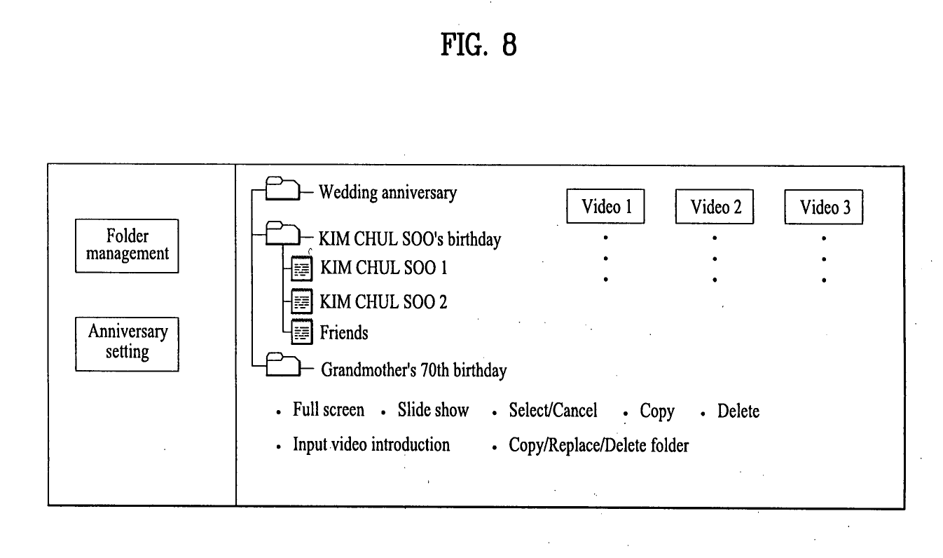

FIG. 8 illustrates other exemplary screen of the display device having an electronic album function according to the present invention. In the exemplary screen of FIG. 8, the user can efficiently manage folders and anniversaries.

If the user selects folder management, the user can set “produce folder”, “delete folder”, and “change folder name” to manage pictures per anniversary. In other words, if the user inputs photo viewing command, video images stored in the first memory or the second memory are displayed. At this time, a lower menu of the display portion as a function for folder management includes “produce folder”, “delete folder”, and “change folder name”. A new folder or a folder having changed name may be set as an anniversary folder at an anniversary setting function.

Therefore, a function for copying, moving and deleting pictures in the folder and inputting text messages in the pictures is located in a lower portion when outputting thumbnail images or the entire screen.

Furthermore, if the user sets an anniversary function, the user can select a desired anniversary and set desired photos at the anniversary per folder or individual photos.

When the set photos are displayed in the display portion, the user can set the photos to be automatically displayed. For example, photos of the anniversary may be displayed as soon as the display portion is powered on. Alternatively, the photos may be set to be displayed in a slide show.

That is, if the user selects the anniversary to view photos related to the anniversary, the user can select any one of the anniversary folder setting and the anniversary photo message. In this case, either the display manner or the slide manner may be selected.

Further, the user can input or store text messages in a desired photo.

As described above, the display device having an electronic album function and the method for controlling the same have the following advantages.

Since functions for managing folders, setting anniversaries, displaying the video data related to the anniversaries, and outputting the audio data are additionally provided, it is possible to manage video images at user's desire.

Although the invention has been discussed for displaying anniversary-related video and audio data in electronic albums, the invention is not limited thereto, but encompasses displaying other events in the electronic albums. For example, the inventive concept of the present invention is equally applicable to other events such as birthdays, mother's days, father's days, valentine's days, etc.

The forgoing embodiments are merely exemplary and are not to be construed as limiting the present invention. The present teachings can be readily applied to other types of apparatuses. The description of the present invention is intended to be illustrative, and not to limit the scope of the claims. Many alternatives, modifications, and variations will be apparent to those skilled in the art.

What is claimed is:

1. A method of controlling an electronic album, the method comprising:
prestoring, in the electronic album, event information associated with at least one event; and
selectively presenting video and/or audio data associated with the at least one event based on the prestored event information.

2. The method according to claim 1, wherein the at least one event includes at least one anniversary.

3. The method according to claim 2, wherein the event information associated with the at least one anniversary includes at least one or more of the following: types of anniversaries, date and time of the anniversaries, persons concerned in the anniversaries, indexes of video and audio data selected by a user, or text messages.

4. The method according to claim 1, wherein when a certain event among the at least one event has occurred, the selectively presenting step includes:
automatically retrieving prestored video and/or audio data associated the certain event from a memory based on the event information associated with the certain event; and
presenting the retrieved video and audio data in the electronic album.

5. The method according to claim 1, wherein the event information includes display type information identifying a display mode of the video data for each event.

6. The method according to claim 5, wherein the display mode of the video data includes an entire screen display mode, a thumbnail image display mode, or a slide mode.

7. The method according to claim 1, wherein the presenting step presents the video and/or audio data currently being received through broadcasting in a manner identified in the event information or in a random manner.

8. The method according to claim 1, wherein the presenting step presents the video and/or audio data on a remote video/audio display device through a network server.

9. The method according to claim 1, wherein the prestoring step receives the event information associated with the at least one event from at least one user, wherein the at least one user can selectively modify the prestored event information.

10. An electronic album comprising:
a memory to prestore event information associated with at least one event; and
a controller to selectively present video and/or audio data associated with the at least one event based on the prestored event information.

11. The electronic album according to claim 10, wherein the at least one event includes at least one anniversary.

12. The electronic album according to claim 11, wherein the event information associated with the at least one anniversary includes at least one or more of the following: types of anniversaries, date and time of the anniversaries, persons concerned in the anniversaries, indexes of video and audio data selected by a user, or text messages.

13. The electronic album according to claim 10, wherein when a certain event among the at least one event has occurred, the controller automatically retrieves prestored video and/or audio data associated the certain event from a memory based on the event information associated with the certain event, and presents the retrieved video and audio data in the electronic album.

14. The electronic album according to claim 10, wherein the event information includes display type information identifying a display mode of the video data for each event.

15. The electronic album according to claim 14, wherein the display mode of the video data includes an entire screen display mode, a thumbnail image display mode, or a slide mode.

16. The electronic album according to claim 10, wherein the controller presents the video and/or audio data currently being received through broadcasting in a manner identified in the event information or in a random manner.

17. The electronic album according to claim 10, wherein the controller presents the video and/or audio data on a remote video/audio display device through a network server.

18. The electronic album according to claim 10, further comprising:
a user interface to receive the event information associated with the at least one event from at least one user for storage in the memory, whereby the at least one user can selectively modify the prestored event information.

19. A method for controlling an electronic album, the method comprising:
setting a folder of images to be stored in a memory in accordance with a user's request;
displaying the images of the set folder;
editing the folder at the user's request referring to the displayed images; and
displaying the edited folder and additional messages in accordance with the user's request to control the electronic album.

20. The method according to claim 19, wherein the setting step includes setting a folder per anniversary and group in accordance with the user's request.

21. The method according to claim 19, wherein the editing step includes:
copying, moving, and/or deleting pictures in the set folder; and
associating messages input by the user for the pictures.

22. The method according to claim 19, wherein the step of displaying the images displays the images stored in the set folder in an automatic mode or a slide mode.
